(19) United States
(12) Patent Application Publication
(10) Pub. No.: US 2016/0307836 A1
(43) Pub. Date: Oct. 20, 2016

(54) SEMICONDUCTOR MEMORY DEVICE BIT LINE TRANSISTOR WITH DISCRETE GATE

(71) Applicant: Macronix International Co., Ltd., Hsin-Chu (TW)

(72) Inventors: Ya Jung TSai, Hsin-Chu (TW); Lan Ting Huang, Hsin-Chu (TW); Kuo NaiPing, Hsin-Chu (TW); Chun-Lien Su, Hsin-Chu (TW)

(21) Appl. No.: 14/687,015

(22) Filed: Apr. 15, 2015

(51) Int. Cl. H01L 23/528; H01L 29/78; H01L 29/08; H01L 27/105

(52) U.S. Cl. CPC H01L 23/528; H01L 27/1052; H01L 29/78; H01L 29/0847

(57) ABSTRACT

A semiconductor memory device is provided including a plurality of diffusion region pairs comprising first and second diffusion regions, wherein each of the diffusion regions comprise source and drain regions of a bit line transistor pair comprising a first bit line transistor and a second bit line transistor and a plurality of bit line transistor gate pairs in contact with the respective diffusion region pairs, wherein the first bit line transistor gate of the bit line transistor gate pairs comprises a gate portion of a first bit line transistor of the first diffusion region and the first bit lite transistor of the second diffusion region, wherein a second bit line transistor gate of the bit line transistor gate pairs comprises a gate portion of the second bit line transistor of the first diffusion region and the second bit line transistor of the second diffusion layer.

### TECHNOLOGICAL FIELD

The present invention generally relates to a structure of a semiconductor device. In particular, the present invention relates to an improved semiconductor memory device bit line transistor structure with discrete bit line transistor gate.

### BACKGROUND

As semiconductor technology continues to be reduced in scale, bit line to bit line pitch gets increasingly smaller in non-volatile memory structures. In traditional bit line transistor structures, bit line transistor (BLT) induced voltage drop (IR drop) and BLT may be inversely proportional, e.g. as the size of the bit cell is reduced the BLT IR drop increases. Further, as a result, smaller global bit line (GBL) spacing may cause process window issues, e.g. a smaller process window and increased coupling noise.

### BRIEF SUMMARY OF EXEMPLARY EMBODIMENTS

Embodiments of the present invention are therefore provided that may provide for a semiconductor memory device bit line transistor structure with discrete BLT gate. In an example embodiment, a semiconductor memory device is provided including a plurality of diffusion region pairs comprising first and second diffusion regions. Each of the diffusion regions comprise source and drain regions of a bit line transistor pair. The semiconductor memory device also includes a plurality of bit line transistor gate pairs in contact with the respective diffusion region pairs. A first bit line transistor gate of the bit line transistor gate pairs comprises a gate portion of a first bit line transistor of the first diffusion region and the first bit lite transistor of the second diffusion region and a second bit line transistor gate of the bit line transistor gate pairs comprises a gate portion of the second bit line transistor of the first diffusion region and a second bit line transistor of the second diffusion layer.

In an example embodiment of the semiconductor memory device, the bit line transistor gates comprise a discrete poly layer. In some example embodiments the semiconductor memory also includes a plurality of conducting line quartets, a first conducting line of the quartet is in electrical contact with a gate contact of the first bit line transistors of a first diffusion region pair, a second conducting line of the quartet is in electrical contact with a gate contact of the first bit line transistors of a second diffusion region pair, a third conducting line of the quartet is in electrical contact with a gate contact of the second bit line transistors of a first diffusion region pair, and a fourth conducting line of the quartet is in electrical contact with a gate contact of the second bit line transistors of the second diffusion region pairs.

In an example embodiment of the semiconductor memory device, the first and second bit line transistor of the respective diffusion regions comprises first and second drain regions and a common source region. In some example embodiments of the semiconductor memory device the first and second drain regions comprise a plurality of drain contacts. In an example embodiment of the semiconductor memory device, the common source region comprises a plurality of source contacts.

In some example embodiments of the semiconductor memory device, the first and second bit line transistor of the respective diffusion regions comprises first and second source regions and a common drain region. In an example embodiment of the semiconductor memory device, the first and second source regions comprise a plurality of source contacts. In some example embodiments of the semiconductor memory device, the common drain region comprises a plurality of drain contacts.

In an example embodiment of the semiconductor memory device, the discrete poly layer layers comprise a first end and a second end and the discrete poly layers further include a width projection at the first and second ends. In some example embodiments, the semiconductor memory device also includes at least one memory sector including four diffusion region pairs and four bit line transistor gate pairs. The four diffusion regions and four bit line transistor gate pairs are disposed in two columns and two rows.

In an example embodiment, the semiconductor memory device also includes a plurality of local bit lines (LBLs) having first and second ends and a first and second memory sector pair. The first memory sector is disposed on a first end and in electrical contact with the LBLs, and the second memory sector is disposed at a second end of the plurality of LBLs. In some example embodiments of the semiconductor memory device, the bit line transistors of the first memory sector comprise odd bit line transistors and the bit line transistors of the second memory sector comprise even bit line transistors.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIGS. 1A and 1B illustrate prior art bit line transistor structures;

FIGS. 1C illustrates an example bit line transistor structure according to an embodiment of the present invention;

FIGS. 2A and 2B illustrate an example memory sector of a bit line structure in accordance with an example embodiment of the present invention;

FIGS. 3A and 3B illustrate an example bit line transistor contact configuration according to an embodiment of the present invention; and

FIG. 4 illustrates an example bit line transistor poly layer according to an embodiment of the present invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a memory device” includes a plurality of such memory devices.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

The inventors have conceived of a semiconductor memory device bit line transistor structure (BLT) which includes discrete BLT gates. The discrete BTL gates may allow for a larger global bit line (GBL) processing window, a larger read window and a smaller BLT area. At a fixed spacing less GBL counts allows for wider line/space width, therefore during lithography inter-metal dielectric (IMD) filling may be improved. The larger read widow may additionally cause the BLT structure to have less GBL to GBL coupling noise over traditional BLT structures. The wider GBL spacing may also reduce the parasitic capacitance reducing cross-talk during read operations. The BLT structure may have comparable or in some instances better, e.g. smaller voltage drop (IR drop) for each BLT.

### Prior Art BLT Structures

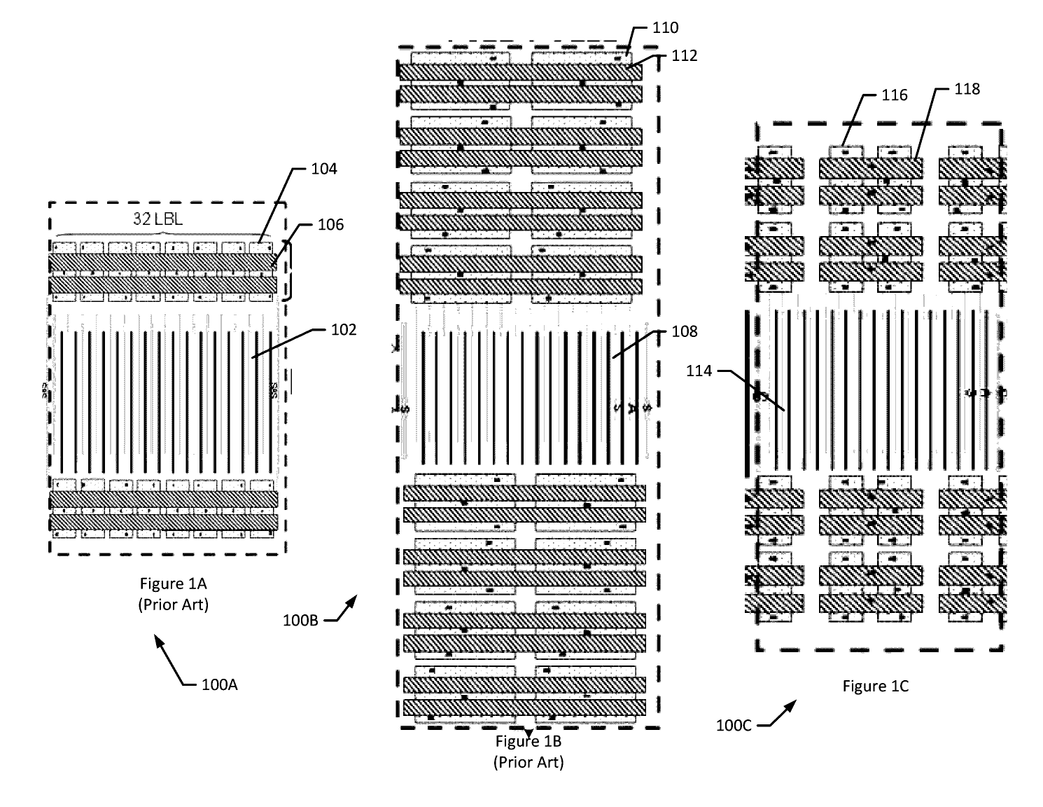

FIGS. 1A and 1B illustrate prior art bit line transistor structures. FIG. 1A depicts a 32 local bit line (LBL) intersection BLT structure 100A, diffusion regions 104, and local bit lines 106. The BLT structure 100A includes 16 diffusion regions 104, each including source and drain regions of two BLTs. The diffusion regions 104 may be disposed in two groups of 8 diffusion regions in a single row. The two groups of 8 diffusion regions 104 may be connected by 2 LBLs 106. The LBL 106 may include the gate region of the respective BLTs.

The BLT structure 100A configuration may include a narrow diffusion region 104 width, causing a smaller overall size of the BLT area, but may also include a significant IR drop.

FIG. 1B depicts a 32 LBL intersection BLT structure 100B, diffusion regions 110, and local bit lines 112. The BLT structure 100B includes 16 diffusion regions 110, each including source and drain portions of two BLTs. The diffusion regions 110 may be disposed in two groups of 8 diffusion regions in two columns of four at each end of the LBLs 112. Each of the four rows of two diffusion regions 110 of the two groups of 8 diffusion regions may be connected by two LBLs 112. The LBLs may include the gate portion of the respective BLTs.

The BLT structure 100B may have a wider diffusion width than BLT structure 100A causing a lower IR drop, but also has a significantly larger BLT structure area.

### BLT Structure with Discrete Poly Gates

FIG. 1C illustrates an example bit line transistor structure according to an embodiment of the present invention. The BLT structure 100C may be a 32 LBL intersection BLT structure including local bit line 114 diffusion regions 116, and BTL gates 118. The BLT structure may include 16 diffusion regions 116, each including source and drain regions of two BLTs. The diffusion regions 116 may be disposed as four diffusion region pairs at each end of the local bit line 114. The diffusion regions 116 may be further disposed in two columns Each of the diffusion region 116 pairs may be connected by two BLT gates 118, e.g. BLT gate pairs. The BLT gates may comprise the gate portion of the respective BLTs. The BLT gates 118 may be a discrete poly layer, e.g. poly of the periphery device doped with a source/drain implant.

The BLT structure 100C may have a wider diffusion region width than BLT structure 100A, which may result in an IR drop comparable to the IR drop of BLT structure 100B. The BLT structure 100C may also have a smaller BLT area than BLT structure 100B.

### Example Memory Sector of a Bit Line Structure

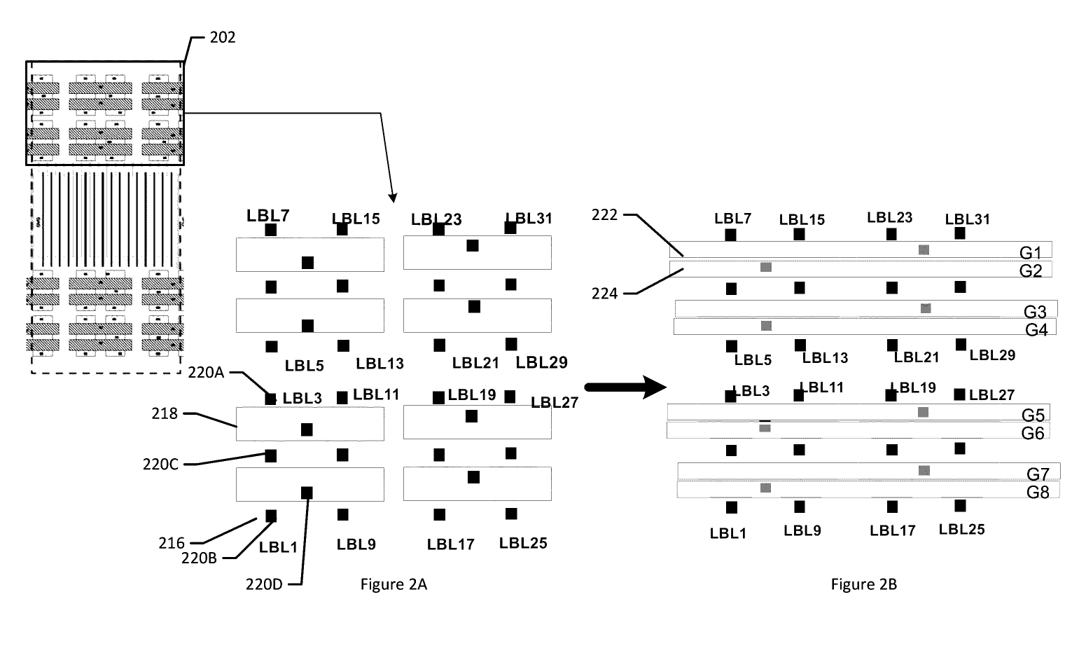

FIGS. 2A and 2B illustrate an example memory sector of a bit line structure in accordance with an example embodiment of the present invention. The memory sector 202 may be a diffusion region and BLT gate group, similar to the diffusion regions 116 and BLT gate 118 groups discussed in FIG. 1C. The BLT structure may include first and second memory sector 202 at each end, e.g. at opposing ends, of the Local Bit line (114). The first memory sector 202 may include control of the odd numbered bit lines, and the second memory sector may include control of the even numbered bit lines. FIG. 2A depicts a zoomed view of a portion of memory sector 202 associated with the odd bit lines, including LBL intersections LBL1, LBL3, LBL5, LBL7, LBL9, LBL11, LBL 13, LBL15, LBL 17, LBL19, LBL 21, LBL23, LBL25, LBL27, LBL29, and LBL31 Similarly, the second memory segment may include even numbered LBL intersections-LBL0-LBL30.

The diffusion regions 216 may have drain contacts 220A and 220B of the BLTs disposed at each end of the diffusion region. A source contact 220C may be disposed in the relative center of the diffusion region 216, between the two drain regions. Although this specification make reference to a BLT structure in which each diffusion region has two drain regions and a common source region, one of ordinary skill in the art would understand that the BLT structure may alternatively have diffusion regions which include two source regions with a common drain region.

Discrete poly BLT gate pairs 218 may be in contact with the diffusion region 216. The BLT gate pairs 218 may be disposed on the diffusion regions, substantially in between the source region and drain region of the diffusion regions. The BLT gates 218 may include a gate contact 220D.

FIG. 2B illustrates the memory sector of FIG. 2A with gate conducting lines 222 and 224. The gate conducting lines may be a metal layer, such as AlCu, copper, dual-damascene, or the like. The gate conducting lines may be configured to provide gating bias to the respective BLTs. The gate conducting lines 222,224 may be disposed as quartets, such as conducting lines quartets G1-G4 and G5-G8. The gate conducting line G1 may be in electrical contact with the gate contact 220D of first BLTs of the second diffusion region 216 pair, associated with LBL 23 and 31. The gate conducting line G2 may be in electrical contact with the gate contact 220D of the first BLTs of the first diffusion region 216 pair, associated with LBL 7 and LBL 15. The third gate conducting line G3 may be in electrical contact with the gate contact of the second BLTs of the second diffusion 216 pair, associated with LBL 21 and 29. The fourth gate conducting line G4 may be in electrical contact with the gate contact 220D of the second BLTs of the first diffusion region 216 pair, associated with LBL 5 and LBL 13. Gate conducting lines 5-8 may be similarly configured and associated with LBLs 1, 3, 9, 11, 17, 19, 27, and 25.

### Example BLT Contact Configurations

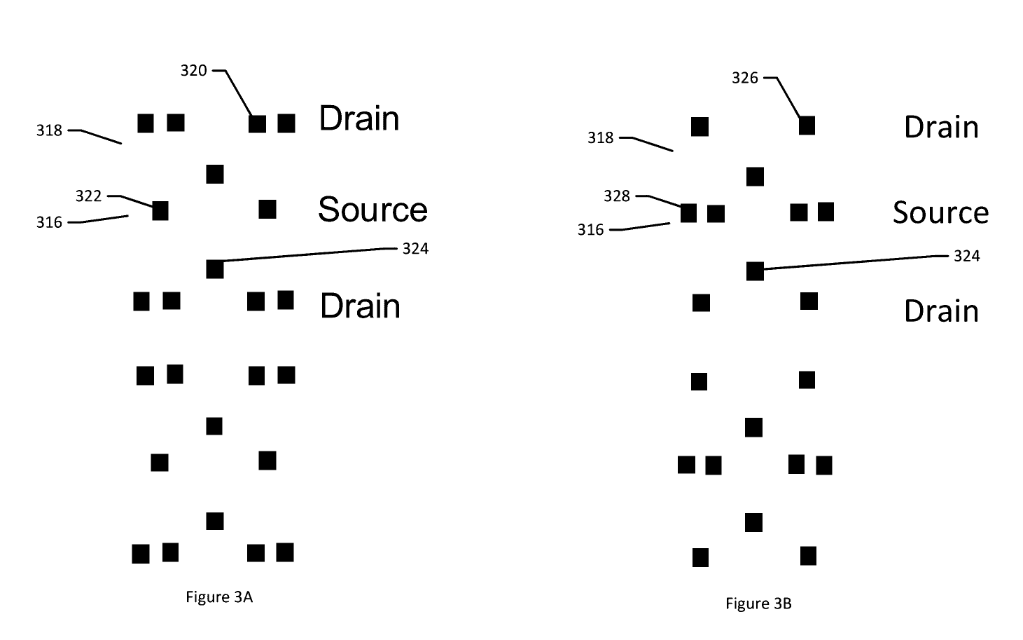

FIGS. 3A and 3B illustrate an example bit line transistor contact configuration according to an embodiment of the present invention. The depicted diffusion region 316 pairs each include a drain region at each end and a source region at the relative center. The BLT gate 318 pairs are in contact with the first and second diffusion regions 316 of the diffusion region pairs between each of the drain regions and the common sources. The BLT source and drain regions may have one, two, or three contacts. As depicted in FIG. 3A, the drain regions each include two contacts 320, the common source regions each include one contact 322, and the BLT gate includes one contact 324. As depicted in FIG. 3B, the common source regions each include two contacts 328 the drain regions each include one contact 326, and the BLT gate includes one contact 324.

### Example BLT Gate Poly Layer

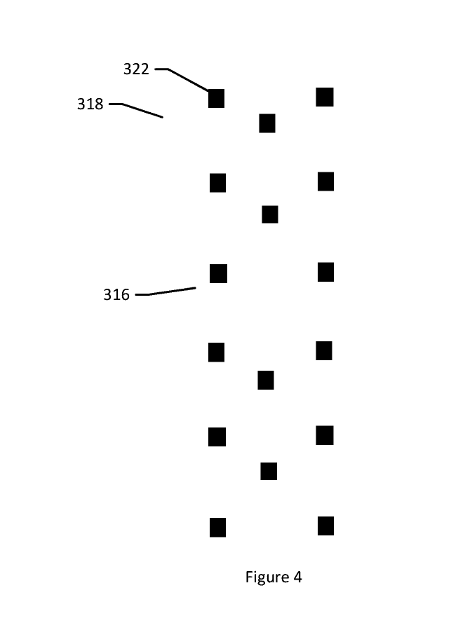

FIG. 4 illustrates an example bit line transistor poly layer according to an embodiment of the present invention. In the depicted example embodiment, the BLT gate poly layer may include width projections at the first and second end. The wider poly layer may have little litho-friendly suffering, improving poly line-end shortening.

The semiconductor memory device BLT structure with discrete BLT gates may reduce the BLT area, reduce GBL to GBL coupling noise, allowing for an enlarged the read window and an enlarged GBL processing window. Additionally, the fabrication of the BLT structure with discrete BLT gates requires no additional mask layers or process flows and may reduce die costs due to the reduction of BLT area minimizing area overhead.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A semiconductor memory device comprising:
a plurality of diffusion region pairs comprising first and second diffusion regions, wherein each of the diffusion regions comprise source and drain regions of a bit line transistor pair comprising a first bit line transistor and a second bit line transistor;
a plurality of bit line transistor gate pairs in contact with the respective diffusion region pairs, wherein the first bit line transistor gate of the bit line transistor gate pairs comprises a gate portion of a first bit line transistor of the first diffusion region and the first bit line transistor of the second diffusion region, wherein a second bit line transistor gate of the bit line transistor gate pairs comprises a gate portion of the second bit line transistor of the first diffusion region and the second bit line transistor of the second diffusion layer, wherein the bit line transistor gates comprise a poly layer which is discrete between adjacent diffusion region pairs such that each bit line transistor gate is only in physical and electrical contact with one pair of the plurality of diffusion region pairs.

2. (canceled)

3. The semiconductor memory device of claim 1 further comprising:
a plurality of conducting line quartets, wherein a first conducting line of the quartet is in electrical contact with a gate contact of the first bit line transistors of a first diffusion region pair, a second conducting line of the quartet is in electrical contact with a gate contact of the first bit line transistors of a second diffusion region pair, a third conducting line of the quartet is in electrical contact with a gate contact of the second bit line transistors of a first diffusion region pair, and a fourth conducting line of the quartet is in electrical contact with a gate contact of the second bit line transistors of the second diffusion region pairs.

4. The semiconductor memory device of claim 1, wherein the first and second bit line transistor of the respective diffusion regions each comprise a first drain region, second drain region, and a common source region.

5. The semiconductor memory device of claim 4, wherein the first and second drain regions comprise a plurality of drain contacts.

6. The semiconductor memory device of claim 4, wherein the common source comprises a plurality of source contacts.

7. The semiconductor memory device of claim 1, wherein the first and second bit line transistor of the respective diffusion regions each comprise a first drain region, second source region, and a common drain region.

8. The semiconductor memory device of claim 7, wherein the first and second source regions comprise a plurality of source contacts.

9. The semiconductor memory device of claim 7, wherein the common drain comprises a plurality of drain contacts.

10. The semiconductor memory device of claim 2, wherein the discrete poly layer layers comprise a first end and a second end, wherein the discrete poly layers further comprise a width projection at the first and second ends.

11. The semiconductor memory device of claim 1 further comprising:
at least one memory sector comprising:
four diffusion region pairs and four bit line transistor gate pairs,
wherein the four diffusion regions and four bit line transistor gate pairs are disposed in two columns and two rows.

12. The semiconductor memory device of claim 11 further comprising:
a plurality of local bit lines (LBLs) having a first and second end; and
a first and second memory sector pair, wherein the first memory sector is disposed on a first end an in electrical contact with the LBLs, and the second memory sector is disposed at a second end of the plurality of LBLs.

13. The semiconductor memory device of claim 12, wherein the bit line transistors of the first memory sector comprise odd bit line transistors and the bit line transistors of the second memory sector comprise even bit line transistors.
